(19) United States
(12) Patent Application Publication
(10) Pub. No.: US 2017/0105287 A1
(43) Pub. Date: Apr. 13, 2017

(54) Process of Producing Electronic Component and an Electronic Component

(71) Applicant: Tyco Electronics Corporation, Berwyn, PA (US)

(72) Inventors: Michael A. Oar, San Francisco, CA (US); Shallu Soneja, Mountain View, CA (US); Gokce Gulsoy, San Jose, CA (US)

(73) Assignee: Tyco Electronics Corporation, Berwyn, PA (US)

(21) Appl. No.: 14/881,034

(22) Filed: Oct. 12, 2015

(51) Int. Cl. H05K 3/32; H05K 1/09

(52) U.S. Cl. CPC H05K 3/32; H05K 1/09

(57) ABSTRACT

Electronic components and processes of producing electronic components are disclosed. A process of producing a component includes positioning a substrate having a non-planar surface, applying a metalizing material on the surface, and energetically beam-melting the metalizing material to produce a metalized electrical contact on the component. A component includes a substrate having a non-planar surface, and a printed and energetically beam-melted metalized electrical contact positioned on the non-planar surface. Additionally or alternatively, a component includes a substrate having a surface, and a rotationally-applied and energetically beam-melted metalized electrical contact positioned on the substrate.

### FIELD OF THE INVENTION

The present invention is directed to electronic components and processes or producing electronic components. More particularly, the present invention is directed to energetically-beam melting.

### BACKGROUND OF THE INVENTION

Known electrical contacts and terminals typically three-dimensional (3D) structures which are produced in a roll-to-roll process. The typical process starts with a flat metal feedstock and then performs two steps: 1) electroplating of the electrical contact or electroplating of a diffusion barrier followed by electroplating of the contact, 2) stamped and formed into the final 3D structures. Depending on the application and metals used, the process can start with electroplating and then forming or vice versa.

The process of printing and energetic beam melting to produce electrical contacts over two-dimensional (2D) surfaces has shown contact property improvements. See, for example, U.S. Patent Publication No. 2014/0097002, which is hereby incorporated by reference in its entirety. Printing and energetic beam melting over 2D surfaces requires that the part be stamped and formed after the metal deposition process, which works for some metal contact and diffusion barrier materials, but not all. Frequently, product specifications require that the contacts and terminals are stamped and formed before the precious metal deposition step in order to reduce likelihood of the precious metal contact being damaged during the forming process. Since energetic beam melting is a line of sight method, energetic beam melting contact finishes over 3D surfaces has not been accomplished in known processes.

Deposition of conductive inks via different printing technologies is a growing technology, with limitations on compatibility for existing techniques. Such limitations render it difficult to utilize the perceived selectivity and ability to produce lower feature-sized electrical contacts. For example, reliance upon metallization techniques on printed features is problematic because they are very complicated thermodynamic and kinetic processes.

Flexibility and breadth of use for electrical contact layers is highly desirable. Prior techniques have not had sufficient control of properties associated with electrical contact layers and, thus, have been limited in application. For example, prior techniques have not adequately permitted inclusion of nanocrystalline structures and/or amorphous structures, permitted creation of medium or larger grains, permitted pore-free or substantially pore-free layers, permitted a gradient of elemental or compositional metals or alloys, permitted formation of a grain boundary strengthened by grain boundary engineering, permitted grain pinning, permitted higher surface hardness, permitted higher wear resistance, permitted diffusion of elements or formation of an interdiffusion layer, permitted higher corrosion resistance, or permitted combinations thereof.

Electroplating of electrical contacts is a common process which requires large volumes of plating bath chemicals, large area physical footprint, and consumes large quantities of precious metals. Due to environmental regulations, electroplating lines are typically segregated to specific geographic zones and undergo high levels of regulatory scrutiny.

An electronic component and process of producing an electronic component that show one or more improvements in comparison to the prior art would be desirable in the art.

### BRIEF DESCRIPTION OF THE INVENTION

In an embodiment, a process of producing a component, the process including positioning a substrate having a non-planar surface, applying a metalizing material on the surface and energetically beam-melting the metalizing material to produce a metalized electrical contact on the component.

In another embodiment, a component includes a substrate having a non-planar surface, and a printed and energetically beam-melted metalized electrical contact positioned on the non-planar surface.

In another embodiment, a component includes a substrate having a non-planar surface, and a rotationally-applied and energetically beam-melted metalized electrical contact positioned on the substrate.

Other features and advantages of the present invention will be apparent from the following more detailed description, taken in conjunction with the accompanying drawings, which illustrate, by way of example, the principles of the invention.

### BRIEF DESCRIPTION OF THE DRAWINGS

FIG. 1 is a schematic diagram of an embodiment of a process of producing an electronic component including energetically-beam melting, according to the disclosure.

FIG. 2 is a schematic diagram of an embodiment of a process of producing an electronic component with a silane-derived layer, the process including energetically-beam melting, according to the disclosure.

FIG. 3 is a schematic diagram of an embodiment of a process of producing an electronic component having a non-planar surface, including printing of the metalizing material and energetically-beam melting the metalizing material, according to the disclosure.

FIG. 4 is a schematic diagram of an embodiment of a process of producing an electronic component having a non-planar surface, including printing of the metalizing material.

FIG. 5 is a schematic diagram of an embodiment of a process of producing an electronic component having a non-planar surface, including printing of the metalizing material.

FIG. 6 shows an exemplary printed substrate, according to the present disclosure.

FIG. 7 shows an exemplary printed substrate, according to another embodiment of the present disclosure.

FIG. 8 shows an exemplary printed substrate, according to another embodiment of the present disclosure.

Wherever possible, the same reference numbers will be used throughout the drawings to represent the same parts.

### DETAILED DESCRIPTION OF THE INVENTION

Provided are electronic components and processes of producing electronic components. Embodiments of the present disclosure, for example, in comparison to concepts failing to include one or more of the features disclosed herein, permit inclusion of nanocrystalline structures and/or amorphous structures, permit creation of medium or larger grains, such as grains from about 0.5 μm to about 4 μm grains, permit pore-free or substantially pore-free layers, permit a gradient of elemental or compositional metals or alloys, permit formation of a grain boundary strengthened by grain boundary engineering via alloying element/compound additions, permit formation of a grain boundary pinning via alloying elements and insoluble particle, permit higher surface hardness, permit higher wear resistance, permit diffusion of elements or formation of an interdiffusion layer, permit higher corrosion resistance, or permit combinations thereof. The method, according to embodiments of the present disclosure, includes a process that is more environmentally friendly and includes selective deposition of precious metals that do not require electroplating. Processes, according to embodiments of the present disclosure, include higher throughput speeds, smaller footprint, and reduced precious metal consumption. In addition to process advantages, the technique generates desirable grain structures, alloys, and microstructures that provide desired physical properties.

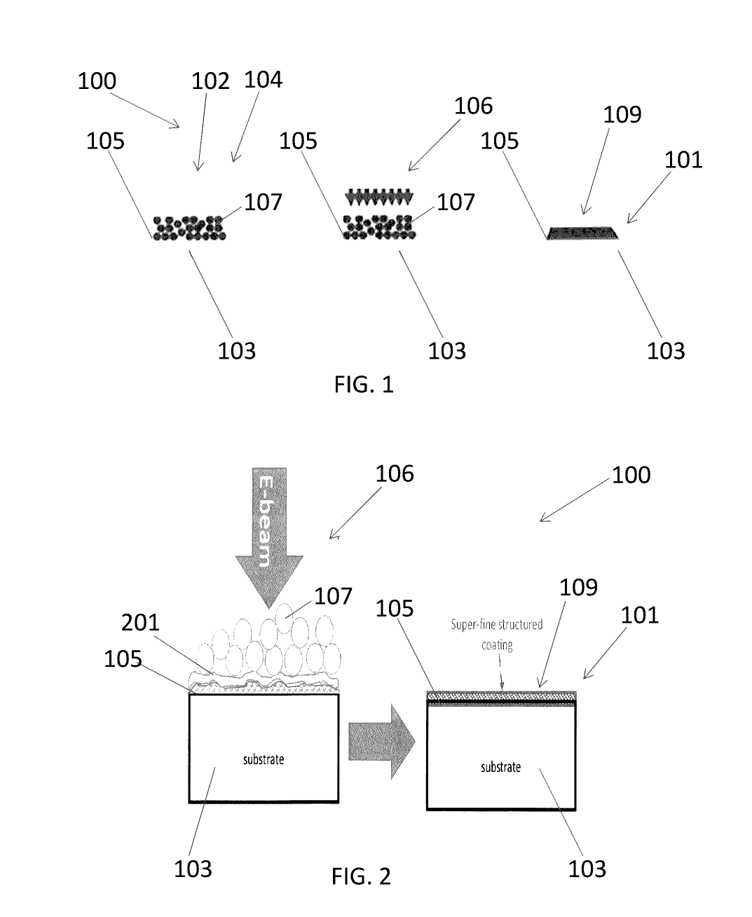

Referring to FIG. 1, in one embodiment, a process 100 of producing a component 101 includes positioning (step 102) a substrate 103 having a surface 105, applying (step 104) a metalizing material 107 on the surface 105, and energetically beam-melting (step 106) the metalizing material 107 to produce a metalized electrical contact 109 on the component 101. The substrate 103 is not particularly limited and may be any suitable substrate material. For example, suitable substrate materials include, but are not limited to, copper (Cu), copper alloys, nickel (Ni), nickel alloys, aluminum (Al), aluminum alloys, steel, steel derivatives, or combinations thereof.

The surface 105 includes a non-planar geometry. In one embodiment, the surface 105 a non-planar surface, for example, being stepped, angled, cuboid, curved, circular, elliptical or any other surface that includes surfaces that deviate from a planar surface. In one embodiment, the surface 105 is or includes a non-metallic and non-conductive material.

Although not shown, a diffusion barrier layer may be applied to the substrate 103 prior to application of the metalizing material 107 to reduce or eliminate diffusion of the substrate material. The barrier layer includes any suitable barrier material, such as, but not limited to, nickel (Ni), titanium (Ti), molybdenum (Mo), tungsten (W), tantalum (Ta), niobium (Nb), zirconium (Zr), vanadium (V), chromium (Cr), iron (Fe), cobalt (Co), manganese (Mn), iron (Fe), hafnium (Hf), rhenium (Re), zinc (Zn), or a combination thereof. The composition of the diffusion barrier layer corresponds with the composition of the substrate and the metalizing material 107.

The applying (step 104) is or includes any printing technique capable of selectively placing the metalizing material 107 directly on the surface 105 or indirectly on the surface 105, for example, through one or more additional interlayers 201, as is shown in FIG. 2. Metalizing material 107 includes metallic components for formation of the metalized electrical contact 109.

In one embodiment, the interlayer(s) 201 is a silane-derived layer between the substrate 103 and the metalizing layer 107. The silane-derived layer is applied prior to the applying (step 104) of the metalizing layer 107 and the energetically beam-melting (step 106). In a further embodiment, the silane-derived layer is applied by hydroxylation, silanization, and immersion. Nanoparticles are deposited on the silane layer from the colloid solution.

To deposit nanoparticles on the silane layer, the silanized substrate is immersed or otherwise contacted with a colloid solution. The colloid solution contains dispersed nanoparticles formed by reducing a gold salt using a mild reducing agent. Without presence of the colloid, metalizing layer 107 cannot be deposited. Particles suitable for use in the colloid include particles having a maximum dimension from about 10 nm to about 10 microns.

In one embodiment, the interlayer 201 is a silane coating. The silane coating may be applied according to known silane coating techniques. In one embodiment, the silane coating is provided by formation of hydroxyl/oxide groups on the surface of the substrate by immersing the substrate into i) Piranha solution, ii) Boiling water/steam, iii) alkaline cleaning solution (sodium phosphate+sodium carbonate solution @˜75° C.) and thereafter immersing the substrate into 1 part organosilane: 4 parts methanol solution for 24 h. To form the colloid solution for metalizing layer 107, a gold salt is brought to a boil and a reducing agent is added. The concentration of the reducing agent in the solution determines the size of suspended particles. In one embodiment, the silanized substrate is immersed into gold colloid solution for 1-5 days for particles to be self-assembled on the substrate surface. Known techniques for the silane formation and colloid formation are described in G. Frens, “Controlled Nucleation for the Regulation of the Particle Size in Monodisperse Gold Suspensions”, Nature Physical Science, Vol. 241, p. 20 (1973); K. C. Grabar et al., “Preparation and Characterization of Au Colloid Monolayers”, Analytical Chemistry, Vol. 67, p. 735 (1995) and; A. D. Kammers, S. Daly, “Self-Assembled Nanoparticle Surface Patterning for Improved Digital Image Correlation in a Scanning Electron Microscope”, Experimental Mechanics, Vol. 53, p. 1333 (2013), each of which is incorporated by reference in their entirety.

Printing of metalizing material 107 over non-planar surfaces is accomplished by any suitable process for printing material onto non-planar surfaces. Suitable processes include, for example, contact roll-to-roll methods including flexographic, or offset printing, rotary screen, as well as non-contact methods when combined with 3D automated movement including discrete droplet jetting, filament dispensing, spray coating, aerosol jet, and inkjet.

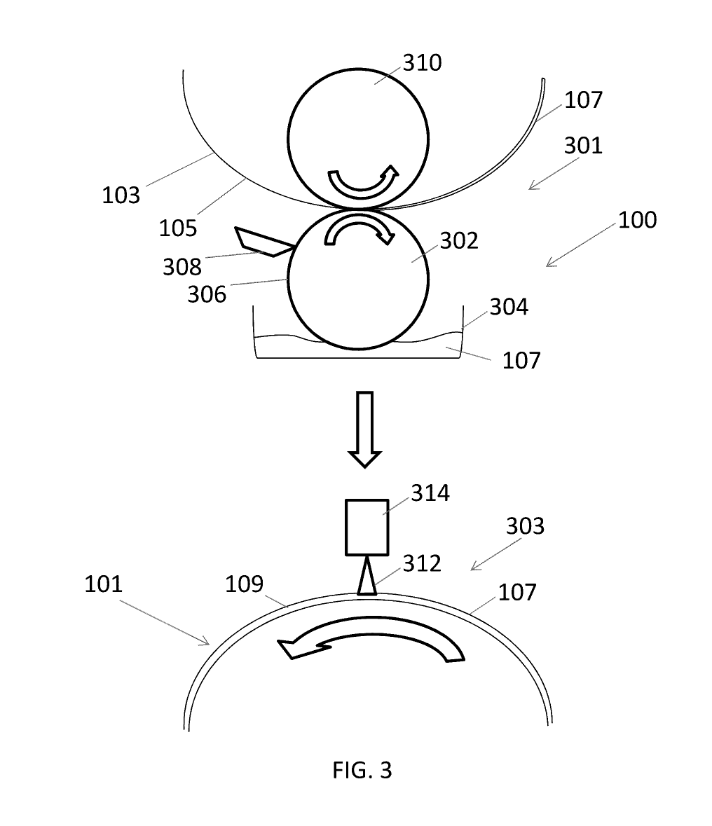

Referring to FIG. 3, in one embodiment, the process 100 of producing a component 101 includes printing a metalizing material 107 onto a substrate 103 having a non-planar surface 105 (step 301), and energetically beam-melting (step 303) the metalizing material 107 to produce a metalized electrical contact 109 on the component 101. Although not so limited, FIG. 3 shows a printing by a gravure printing process (step 301). This process method permits processing of substrates having a non-planar surface. As shown in FIG. 3, the process includes printing by using a gravure cylinder 302 that is rotated and partially immersed in a vessel 304 that includes metalizing material 107. The gravure cylinder 302 includes a print surface 306 that has features imprinted thereon to receive the metalizing material 107. The gravure cylinder rotates and comes into contact with a knife 308 that removes excess metalizing material 107. After the excess metalizing material 107 is removed, the gravure cylinder contacts substrate 103, which contacts an impression cylinder 310, which applies pressure to imprint the metalizing material 107 onto the substrate 103. In one embodiment, the imprint on the substrate 103 corresponds to desired electrical contact locations. The energetic beam melting (step 303) is performed by contacting the metalizing material 107 printed onto the surface of substrate 103 with an energetic beam 312 from an energetic beam source 314 to form a metalized electrical contact 109.

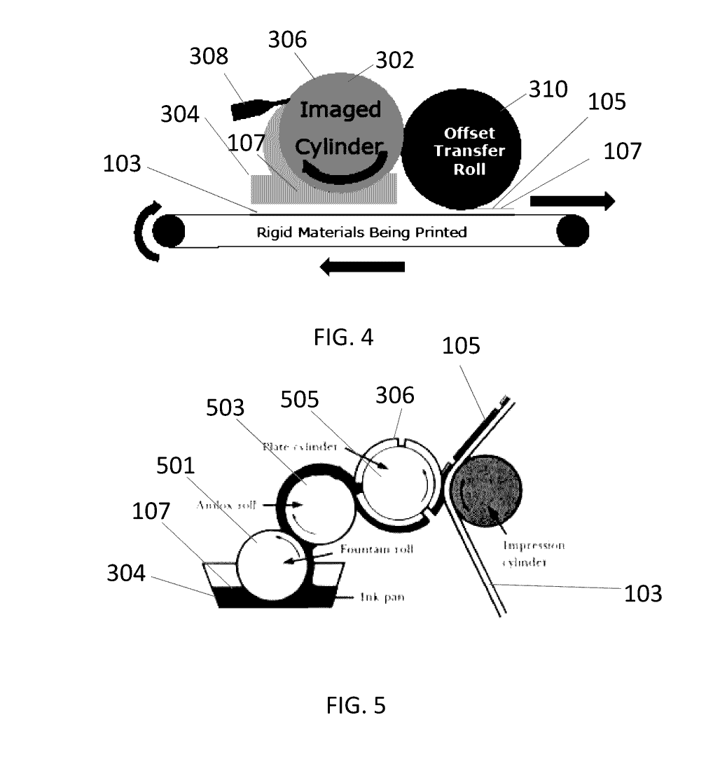

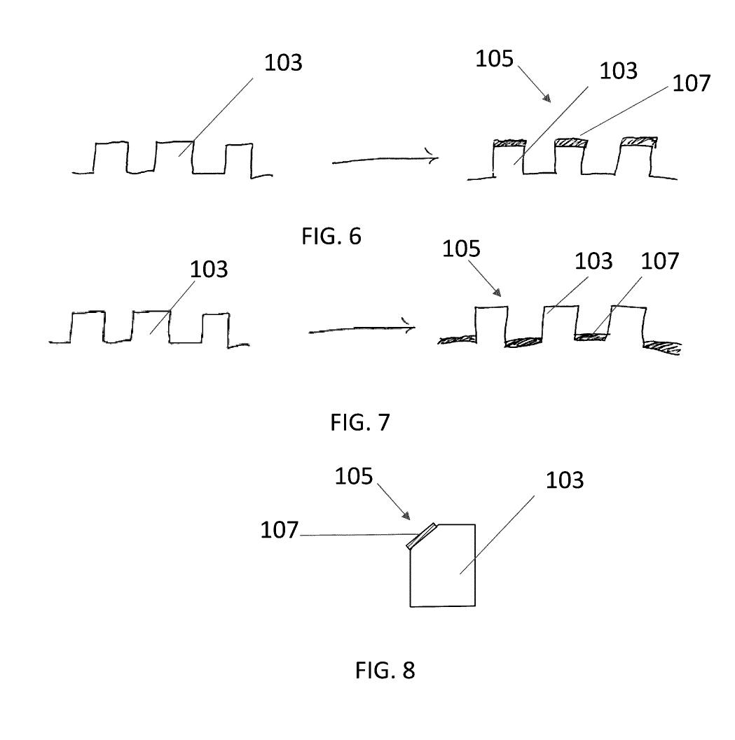

Referring to FIG. 4, in one embodiment, the process 100 of producing a component 101 (not shown in FIG. 4) includes printing a metalizing material 107 onto a substrate 103. Although not so limited, FIG. 4 shows a printing by an offset gravure printing process. This process method permits processing of substrates having a non-planar surface, such as stepped or angled surfaces (see, for example, FIGS. 6-8). Alternatively, the metalizing material 107 may be applied to provide a non-planar surface. As shown in FIG. 4, the process includes printing by using a gravure cylinder 302 that is rotated and partially immersed in a vessel 304 that includes metalizing material 107. The gravure cylinder 302 includes a print surface 306 that has features imprinted thereon to receive the metalizing material 107. The gravure cylinder rotates and comes into contact with a knife 308 that removes excess metalizing material 107. After the excess metalizing material 107 is removed, the gravure cylinder contacts substrate 103, which contacts an impression cylinder 310, which applies pressure to imprint the metalizing material 107 onto the substrate 103 to provide a printed surface. Although not shown, after the printing process shown in FIG. 4, the substrate is subjected to energetic beam melting, such as traversing an energetic beam from an energetic beam source over the substrate and metalizing material 107 to form a metalized electrical contact 109.

Referring to FIG. 5, in one embodiment, the process 100 of producing a component 101 (not shown in FIG. 5) includes printing a metalizing material 107 onto a substrate 103. Although not so limited, FIG. 4 shows a printing by a flexographic printing process. This process method permits processing of substrates having a non-planar surface, such as stepped or angled surfaces (see, for example, FIGS. 6-8). Alternatively, the metalizing material 107 may be applied to provide a non-planar surface. As shown in FIG. 5, the process includes printing by using a supply cylinder 501 that is rotated and partially immersed in a vessel 304 that includes metalizing material 107. The supply cylinder rolls against an anilox roll 503. The anilox roll 503 rolls against and transfers the metalizing material 107 to a plate cylinder 505. The plate cylinder 505 includes a print surface 306 that has features imprinted thereon to receive the metalizing material 107. After the metalizing material 107 is applied to the plate cylinder 505, the plate cylinder imprints the metalizing material 107 and applies pressure onto the substrate 103 to provide a printed surface. Although not shown, after the printing process shown in FIG. 5, the substrate is subjected to energetic beam melting, such as traversing an energetic beam from an energetic beam source over the substrate and metalizing material 107 to form a metalized electrical contact 109.

Other processes suitable for printing the metalizing material 107 onto the substrate include, but are not limited to, rotational printing, screen printing, pad printing and/or offset printing.

FIGS. 6-8 show alternate embodiments of substrates 103 having non-planar surfaces 105 that have been printed, according to an embodiment of the present disclosure. As shown in FIGS. 6-7, the substrate includes a stepped geometry, wherein the metalizing material 107 is applied either at the peak of the step (FIG. 6) or at the trough of the step (FIG. 7). In other embodiments, the printing may be provided such that there is a combination of locations for the metalizing material or the metalizing material 107 may be applied in a predetermined pattern. As shown in FIG. 8, the metalizing material 107 is printed on a non-planar surface 105 that is angled.

The metalizing material 107 is any suitable material capable of being formed and/or processed into the metalized electrical contact 109. In one embodiment, the metalizing material 107 includes conductive nanoparticles having maximum dimensions of between 10 nm and 10 microns. Suitable metallic components for inclusion in the metalizing material 107 include, but are not limited to, gold (Au), silver (Ag), tin (Sn), molybdenum (Mo), titanium (Ti), palladium (Pd), platinum (Pt), rhodium (Rh), iridium (Ir), aluminum (Al), ruthenium (Ru), or combinations thereof. In one embodiment with gold in the metalizing material 107, the metalizing material 107 has a volatile organic compound of less than 2%, by volume.

The energetic beam melting is achieved by any suitable techniques. Suitable techniques include, but are not limited to, applying a continuous energetic beam (for example, from a CO₂ laser or electron beam), applying a pulsed energetic beam (for example, from a neodymium yttrium aluminum garnet laser), applying a focused beam, applying a defocused beam, or performing any other suitable beam-based technique. Energetic beam melting is with any suitable parameters, such as, penetration depths, pulse duration, beam diameters (at contact point), beam intensity, and wavelength.

Energetic beam melting, according to the present disclosure, utilizes a line of sight method with manipulation of the beam and/or workpiece to provide beam contact with the non-planar surface. For example, suitable processes, according to the present disclosure, include in-process changes to the beam focal distance or substrate z-height for surfaces that are within the line of sight as well as 3D automated substrate movement to access non line-of-sight surfaces. For example, in one embodiment, the substrate 103 with the metalizing material 107 is manipulated robotically to various orientations with respect to the energetic beam.

Suitable penetration depths depend upon the composition and the beam energies. For example, for Cu or Cu-containing compositions, suitable penetration depths at 20 kV include, but are not limited to, between 1 and 2 micrometers, between 1 and 1.5 micrometers, between 1.2 and 1.4 micrometers, or any suitable combination, sub-combination, range, or sub-range therein. For Cu or Cu-containing compositions, suitable penetration depths at 60 kV include, but are not limited to, between 7 and 9 micrometers, between 7.5 and 8.5 micrometers, between 7.8 and 8.2 micrometers, or any suitable combination, sub-combination, range, or sub-range therein.

For Ag or Ag-containing compositions, suitable penetration depths at 20 kV include, but are not limited to, between 1 and 2 micrometers, between 1 and 1.5 micrometers, between 1.2 and 1.4 micrometers, or any suitable combination, sub-combination, range, or sub-range therein. For Ag or Ag-containing compositions, suitable penetration depths at 60 kV include, but are not limited to, between 8 and 9 micrometers, between 8.2 and 8.8 micrometers, between 8.4 and 8.6 micrometers, or any suitable combination, sub-combination, range, or sub-range therein.

For Au or Au-containing compositions, suitable penetration depths at 20 kV include, but are not limited to, between 0.5 and 1.5 micrometers, between 0.7 and 1.3 micrometers, between 0.8 and 1 micrometers, or any suitable combination, sub-combination, range, or sub-range therein. For Au or Au-containing compositions, suitable penetration depths at 60 kV include, but are not limited to, between 3 and 7 micrometers, between 4 and 6 micrometers, between 4.5 and 5.5 micrometers, or any suitable combination, sub-combination, range, or sub-range therein.

Suitable pulse durations include, but are not limited to, between 4 and 24 microseconds, between 12 and 100 microseconds, between 72 and 200 microseconds, between 100 and 300 microseconds, between 250 and 500 microseconds, between 500 and 1,000 microseconds, or any suitable combination, sub-combination, range, or sub-range therein.

Suitable beam widths include, but are not limited to, between 25 and 50 micrometers, between 30 and 40 micrometers, between 30 and 100 micrometers, between 100 and 150 micrometers, between 110 and 130 micrometers, between 120 and 140 micrometers, between 200 and 600 micrometers, between 200 and 1,000 micrometers, between 500 and 1,500 micrometers, or any suitable combination, sub-combination, range, or sub-range therein.

Suitable beam intensities include, but are not limited to, having a power output of between 2000 watts to 10 kilowatts, between 10 kilowatts to 30 kilowatts, between 30 to 100 kilowatts, between 0.1 and 2,000 watts, between 1,100 and 1,300 watts, between 1,100 and 1,400 watts, between 1,000 and 1,300 watts, between 50 and 900 watts, between 4.5 and 60 watts, between 1 and 2 watts, between 1.2 and 1.6 watts, between 1.2 and 1.5 watts, between 1.3 and 1.5 watts, between 200 and 250 milliwatts, between 220 and 240 milliwatts, or any suitable combination, sub-combination, range, or sub-range therein.

In embodiments utilizing the laser for the energetic beam melting, suitable wavelengths include, but are not limited to, between 10 and 11 micrometers, between 9 and 11 micrometers, between 10.5 and 10.7 micrometers, between 1 and 1.1 micrometers, between 1.02 and 1.08 micrometers, between 1.04 and 1.08 micrometers, between 1.05 and 1.07 micrometers, or any suitable combination, sub-combination, range, or sub-range therein.

While the invention has been described with reference to one or more embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims. In addition, all numerical values identified in the detailed description shall be interpreted as though the precise and approximate values are both expressly identified.

What is claimed is:

1. A process of producing a component, the process comprising:
positioning a substrate having a non-planar surface;
applying a metalizing material on the surface; and
energetically beam-melting the metalizing material to produce a metalized electrical contact on the component.

2. The process of claim 1, wherein the non-planar surface is a stepped surface.

3. The process of claim 1, wherein the non-planar surface is an angled surface.

4. The process of claim 1, wherein the non-planar surface is cuboid.

5. The process of claim 1, wherein the non-planar surface is curved.

6. The process of claim 1, wherein the surface is a non-metallic and non-conductive material.

7. The process of claim 1, wherein the substrate includes a material selected from the group consisting of copper, copper alloys, nickel, nickel alloys, aluminum, aluminum alloys, steel, steel derivatives, or combinations thereof.

8. The process of claim 1, wherein the substrate is nickel-plated phosphor bronze.

9. The process of claim 1, wherein the substrate is a nickel-plated copper alloy.

10. The process of claim 1, wherein the applying is applied by a process selected from gravure printing, rotational printing, flexographic printing, offset printing, screen printing and pad printing.

11. The process of claim 1, wherein the applying is by immersion in a colloidal suspension.

12. The process of claim 1, wherein the metalizing material is selected from the group consisting of nickel, titanium, molybdenum, tungsten, tantalum, niobium, zirconium, vanadium, chromium, iron, cobalt, and combinations thereof.

13. The process of claim 1, wherein the metalizing material includes silver.

14. The process of claim 1, wherein the metalizing material includes gold and has volatile organic compounds of less than 2%, by volume.

15. The process of claim 1, wherein the metalizing material is applied directly on the surface.

16. The process of claim 1, wherein the metalizing material is not applied directly on the surface.

17. The process of claim 1, further comprising applying a silane-derived layer between the substrate and the metalizing layer prior to the applying of the metalizing layer and the energetically beam-melting.

18. The process of claim 1, wherein the process is devoid of electroplating.

19. A component, comprising:
a substrate having a non-planar surface; and
a printed and energetically beam-melted metalized electrical contact positioned on the non-planar surface.

20. A component, comprising:
a substrate having a non-planar surface; and
a rotationally-applied and energetically beam-melted metalized electrical contact positioned on the substrate.
